(19) United States
(12) Patent Application Publication
(10) Pub. No.: US 2001/0010305 A1
(43) Pub. Date: Aug. 2, 2001

(54) Precision polishing method and apparatus of substrate

(76) Inventor: Kazuo Takahashi, Kawasaki-shi (JP)

Correspondence Address: FITZPATRICK CELLA HARPER & SCINTO, 30 ROCKEFELLER PLAZA, NEW YORK, NY, 10112, US

(21) Appl. No.: 09/794,353

(22) Filed: Feb. 28, 2001

Related U.S. Application Data
(62) Division of application No. 09/207,916, filed on Dec. 9, 1998.

(30) Foreign Application Priority Data
Dec. 10, 1997 (JP) 9-361836
Dec. 10, 1997 (JP) 9-361873
Dec. 8, 1998 (JP) 10-366124

(51) Int. Cl. H01L 21/304

(52) U.S. Cl. 216/89; 156/345

(57) ABSTRACT

Provided are precision polishing methods and apparatus for efficiently and uniformly polishing a surface of a substrate with high precision by efficiently and uniformly distributing a polishing liquid over entire contact surfaces of the substrate and a polishing pad.

A substrate W and a polishing pad P are dipped in a slurry solution S, the substrate W and polishing pad P are rotationally driven, a plurality of rotary vanes are fixed at equal intervals on a peripheral part of a polishing table 1 holding the substrate, the rotational speed of the rotary vanes 5 is periodically changed to increase the pressure of the polishing liquid S between the substrate W and the polishing pad P and create a gap between the substrate W and the polishing pad P, and the polishing liquid S is forced into this gap with aspirating the polishing liquid S from the vicinity of the central part of the polishing pad P by a slurry aspirating device. In this arrangement, the polishing liquid S is uniformly distributed over the entire surface of the substrate W, which enables uniform polishing of the entire surface of the substrate.

### BACKGROUND OF THE INVENTION

1. Field of the Invention

The present invention relates to a precision polishing method and apparatus for precisely polishing such a substrate as a semiconductor substrate or a substrate for display and, more particularly, to a precision polishing method and apparatus for polishing a surface of a substrate, such as a wafer having at least one material for forming a semiconductor integrated circuit in the surface, with high precision, for example, midway in a production process of the semiconductor integrated circuit.

2. Related Background Art

Semiconductor devices tend to be constructed in hyperfine structure or in highly stepped structure and with progress of such tendency they tend to be made using a substrate selected from SOI substrates, semiconductor wafers such as Si, GaAs, or InP, quartz or glass substrates on a surface of which a plurality of island-shape semiconductor regions are formed, and so on. These substrates are required all to have a plane surface in order to form patterned wires or insulating regions by photolithography and the surface is an insulating film or a metal film or a surface of mixture of them. Chemical mechanical polishing (CMP) methods are known as processing means for planarizing such substrates as the wafers with high precision.

The apparatus as illustrated in FIG. 7 is one of apparatus used heretofore in carrying out chemical mechanical polishing (CMP) by the inventor of the present invention. The apparatus has a polishing table 101 equipped with a polishing pad 102 having a relatively large diameter of approximately three to five times the diameter of the substrate 104 such as a wafer, a work holder 103 for detachably holding the substrate 104 such as the wafer as a work on the bottom surface, and a supply nozzle 106 for supplying onto the polishing pad 102 a polishing liquid (a polishing slurry which will also be called simply a slurry solution) 107, which is a suspension in which, for example, fine powder of silicon oxide is mixed in an aqueous solution of potassium hydroxide, and the apparatus is constructed in such structure that while the polishing pad 102 is urged against the substrate 104 so as to keep the polishing pad 102 under predetermined processing pressure, the chemical mechanical polishing is carried out with rotating the polishing table 101, also rotating and rocking the work holder 103, and further supplying the slurry solution 107 to between the polishing pad 102 and the substrate 104 at the same time. In the polishing apparatus of this type, however, the polishing pad has the large diameter and most of the slurry solution supplied onto the polishing pad is scattered by centrifugal force with rotation of the polishing pad at high speed, which was a bottleneck in increasing the speed of chemical mechanical polishing.

For polishing the substrate by use of the polishing pad having the diameter smaller than the diameter of the substrate such as the wafer, there are also suggestions to suggest chemical mechanical polishing apparatus of a type, as illustrated in FIG. 8, in which the substrate is mounted on the polishing table 202 through a substrate holding member 201a and in which while the polishing pad 204 having the diameter smaller than the diameter of the substrate is urged against the substrate 202 so as to keep the polishing pad 204 under predetermined processing pressure, the chemical mechanical polishing is carried out with rotating or linearly moving the polishing table 201, rotating or rocking the polishing head 203 mounted with the polishing pad 204, and further supplying the slurry solution 207 from the supply nozzle 206 onto the polished surface of the substrate 202 at the same time. In the apparatus of this type, no consideration is given to the fundamental problem that polishing characteristics of the polishing pad are proportional to peripheral velocity, i.e., that polishing is not effected at the center of the polishing pad and the polishing speed increases from the center to the circumference, and attempt is made to solve this problem simply by rocking of the polishing head. Further, the apparatus of this type is also arranged to rotate the substrate 202 at the rotational speed of about 500 rpm. Even though the slurry solution 207 is dropped onto the top surface of the substrate 202 as illustrated in FIG. 8, most of the slurry solution 207 is scattered by centrifugal force. Therefore, the apparatus of this type had a drawback of large waste of the slurry solution. In addition, the rotational speeds of the polishing pad 204 and the polishing table 201 are as high as 100 to 500 rpm and the polished surface of the substrate 202 is kept in close fit under pressure with the polishing surface of the polishing pad 204. These posed another problem that the slurry solution 207 did not flow effectively between the contact surfaces of the substrate 202 and the polishing pad 204.

In order to solve the problems as described above, the inventor has studied other apparatus including the apparatus as illustrated in FIG. 9, which had the polishing table 301 for holding the substrate 302 such as the wafer through the substrate holding member 301a, and the polishing head 303 equipped with the detachable polishing pad 304 having the diameter smaller than the diameter of the substrate 302 and was further provided with the supply nozzle 306 for supplying the slurry solution 307 to near the central part of the polishing head 303 and polishing pad 304 and which was constructed in such structure that while the polishing pad was urged against the substrate 302 so as to keep the polishing pad 304 under predetermined processing pressure, the chemical mechanical polishing was carried out with rotating or linearly moving the polishing table 301 at high speed, also rotating or rocking the polishing head 303, and further forcing a constant amount of slurry solution 307 to between the substrate 302 and the polishing pad 304 at the same time.

In the above-stated chemical mechanical polishing apparatus of the type wherein, for supplying the slurry solution to between the polishing pad and the substrate being the work, the slurry solution is supplied through the supply nozzle to the area outside the contact surfaces of the polishing pad and the substrate and on either the polishing pad or the substrate mounted on the polishing table, most of the slurry solution supplied is scattered with rotation of the polishing table to which the polishing pad or the substrate is attached and only part of the slurry solution flows into between the substrate and the polishing pad, so that this part of the slurry solution contributes to the chemical mechanical polishing. In the supply method of the slurry solution in the chemical mechanical polishing apparatus of this type, therefore, only the part flowing onto the contact surfaces of the polishing pad and substrate out of the total amount of the slurry solution supplied contributed to the chemical mechanical polishing and the slurry solution was not supplied in sufficient amount to the central part of the substrate or the polishing pad, so as to make the polishing at the central part of the substrate or the polishing pad insufficient, thus making it difficult to uniformly polish the entire surface of the substrate. Further, it was necessary to supply a large amount of the slurry solution over the amount of slurry solution actually necessary for the polishing, taking account of the scattering of the slurry solution.

In the case of the apparatus constructed in the structure where a supply hole for supplying the slurry solution 307 was bored near the central part of the polishing pad 304 so that the slurry solution was able to be forced in constant quantity to the central part of the polishing pad as illustrated in FIG. 9, the amount of the slurry solution scattered by the centrifugal force was decreased with high-speed rotation of the polishing head 303, because the center of the polishing pad was always located on the polished surface of the substrate. With this apparatus, however, the polishing pad was also in close fit with the polished surface of the substrate because the polishing pad itself was pressed under pressure. Even if the slurry solution was forced out of the vicinity of the central part of the polishing pad, the slurry solution was not always dispersed uniformly over the entire surface of the polishing pad. There were thus some cases in which uniform polishing of the entire surface of the substrate did not result. In FIG. 9 reference numeral 301 designates the polishing table, 301a the substrate holding member, 302 the substrate, and 306 the supply nozzle.

The present invention has been accomplished in view of the above problems not solved yet and an object of the present invention is, therefore, to provide a precision polishing method and apparatus that can efficiently and uniformly polish a surface of a substrate with high precision by efficiently and uniformly distributing the slurry solution over the entire contact surfaces of the substrate and polishing pad without necessitating a large amount of slurry solution more than necessary.

### SUMMARY OF THE INVENTION

The present invention thus provides a precision polishing method of substrate for urging a polishing pad attached to a polishing head under a predetermined processing pressure against a polished surface of a polished substrate and supplying a polishing liquid to between the polishing pad and the polished surface of the polished substrate to polish the polished surface,

wherein at least the polished surface of the polished substrate and a polishing surface of the polishing pad are dipped in the polishing liquid and wherein the polishing liquid is periodically taken from a circumference into between the polished surface of the polished substrate and the polishing surface of the polishing pad by a plurality of rotary vanes fixed to a peripheral part of a polishing table holding the polished substrate.

The present invention also provides a precision polishing apparatus of substrate for urging a polishing pad attached to a polishing head under a predetermined processing pressure against a polished surface of a polished substrate and supplying a polishing liquid to between the polishing pad and the polished surface of the polished substrate to polish the polished surface,

the apparatus comprising a polishing table comprising a substrate holding portion for holding the polished substrate and arranged to be rotationally driven by a first driving means, wherein a plurality of rotary vanes are fixed to a peripheral part of the substrate holding portion of the polishing table, wherein at least the polished surface of the polished substrate and a polishing surface of the polishing pad are dipped in the polishing liquid, and wherein the polishing liquid is periodically taken from a circumference into between the polished surface of the polished substrate and the polishing surface of the polishing pad by rotational movement of the rotary vanes.

The present invention further provides a precision polishing apparatus of substrate comprising a polishing table comprising a substrate holding portion for holding a polished substrate and arranged to be rotationally driven by a first driving means, a polishing head to which a polishing pad is detachably attached so that a polishing surface thereof faces the polished substrate and which is arranged to be rotationally driven by a second driving means, a vertical moving means for vertically moving the polishing head in the axial direction, and an urging means for urging the polishing surface of the polishing pad against the polished substrate, the apparatus being adapted for urging the polishing pad attached to the polishing head under a predetermined processing pressure against the polished surface of the polished substrate and supplying a polishing liquid to between the polishing pad and the polished substrate to polish the polished surface,

wherein a plurality of rotary vanes are fixed to a peripheral part of the substrate holding portion of the polishing table, wherein at least the polished surface of the polished substrate and the polishing surface of the polishing pad are dipped in the polishing liquid, and wherein the polishing liquid is periodically taken from a circumference into between the polished surface of the polished substrate and the polishing surface of the polishing pad by rotational movement of the rotary vanes.

The present invention also provides a precision polishing method of substrate for urging a polishing pad attached to a polishing head under a predetermined processing pressure against a polished surface of a polished substrate and supplying a polishing liquid to between the polishing pad and the polished surface of the polished substrate to polish the polished surface,

wherein at least the polished surface of the polished substrate and a polishing surface of the polishing pad are dipped in the polishing liquid and wherein the polishing liquid is periodically taken from a circumference into between the polished surface of the polished substrate and the polishing surface of the polishing pad by a plurality of variable-angle rotary vanes provided on a peripheral part of a polishing table holding the polished substrate.

The present invention further provides a precision polishing apparatus of substrate for urging a polishing pad attached to a polishing head under a predetermined processing pressure against a polished surface of a polished substrate and supplying a polishing liquid to between the polishing pad and the polished surface of the polished substrate to polish the polished surface,

the apparatus comprising a polishing table comprising a substrate holding portion for holding the polished substrate and arranged to be rotationally driven by a first driving means, wherein a plurality of variable-angle rotary vanes are provided on a peripheral part of the substrate holding portion of the polishing table, wherein at least the polished surface of the polished substrate and a polishing surface of the polishing pad are dipped in the polishing liquid, and wherein the polishing liquid is periodically taken from a circumference into between the polished surface of the polished substrate and the polishing surface of the polishing pad by rotational movement of the variable-angle rotary vanes.

The present invention also provides a precision polishing apparatus of substrate comprising a polishing table comprising a substrate holding portion for holding a polished substrate and arranged to be rotationally driven by a first driving means, a polishing head to which a polishing pad is detachably attached so that a polishing-surface thereof faces the polished substrate and which is arranged to be rotationally driven by a second driving means, a vertical moving means for vertically moving the polishing head in the axial direction, and an urging means for urging the polishing surface of the polishing pad against the polished substrate, the apparatus being adapted for urging the polishing pad attached to the polishing head under a predetermined processing pressure against the polished surface of the polished substrate and supplying a polishing liquid to between the polishing pad and the polished substrate to polish the polished surface,

wherein a plurality of variable-angle rotary vanes are provided on a peripheral part of the substrate holding portion of the polishing table, wherein at least either one of the polished surface of the polished substrate and the polishing surface of the polishing pad is dipped in the polishing liquid, and wherein the polishing liquid is periodically taken from a circumference into between the polished surface of the polished substrate and the polishing surface of the polishing pad by rotational movement of the variable-angle rotary vanes.

The present invention also provides a precision polishing method of substrate for polishing a polished surface while supplying a polishing liquid to between a polishing pad and the polished surface,

the method comprising:

a step of rotating in the polishing liquid a polishing table provided with a plurality of rotary vanes on a peripheral part of a substrate holding portion for holding the polished substrate; and

a step of vertically moving at least either one of a polishing head detachably holding the polishing pad and the polishing table,

wherein the polished surface is polished with taking the polishing liquid from a circumference into between the polished substrate and the polishing pad.

The present invention also provides a precision polishing apparatus of substrate comprising a polishing table detachably holding a polished substrate, and a polishing head detachably holding a polishing pad, the apparatus being adapted for polishing the polished substrate while supplying a polishing liquid to between the polishing pad and the polished substrate,

the apparatus comprising:

a rotating means for rotating the polishing table;

a plurality of rotary vanes provided on a peripheral part of a substrate holding portion of the polishing table;

a vessel retaining the polishing liquid and permitting the plurality of rotary vanes to be dipped in the polishing liquid; and

a vertical driving means for vertically moving at least either one of the polishing head and the polishing table.

The present invention further provides a precision polishing method of substrate for polishing a polished substrate while supplying a polishing liquid to between a polishing pad and the polished substrate,

the method comprising:

a step of rotating a holding means detachably holding either one of the polishing pad and the polished substrate; and

a step of taking the polishing liquid retained in a vessel into between the polishing pad and the polished substrate by a plurality of rotary vanes provided on a peripheral part of the holding means with rotation of the holding means;

whereby the polished surface is polished.

The present invention also provides a precision polishing apparatus of substrate comprising a polishing head and a holding means for holding a polished substrate, the apparatus being adapted for polishing the polished substrate while supplying a polishing liquid to between the polishing head and the holding means,

the apparatus comprising:

a vessel for retaining the polishing liquid;

a plurality of rotary vanes provided on at least either one of the polishing head and the holding means; and

a rotation driving means for rotating at least either one of the polishing head and the holding means having the rotary vanes,

wherein at least either one of the polishing head and the holding means is placed so that the rotary vanes can be dipped in the polishing liquid retained in the vessel.

In the present invention, there are the polishing table which is provided with the substrate holding portion holding the polished substrate and which is arranged to be rotationally driven by the first driving means, the polishing head to which the polishing pad is detachably attached so that the polishing surface thereof faces the polished substrate and which is arranged to be rotationally driven by the second driving means, the vertical moving means for vertically moving the polishing head in the axial direction, and the urging means for urging the polishing surface of the polishing pad against the polished substrate; the plurality of rotary vanes are fixed at equal intervals to the peripheral part of the substrate holding portion of the polishing table; at least the polished surface of the polished substrate and the polishing surface of the polishing pad are dipped in the polishing liquid so as to perform polishing in the polishing liquid; the polishing is carried out with changing the rotational speeds of the polishing table and the polishing head or the processing pressure of the polishing pad at the predetermined periods during the polishing process, thereby increasing the pressure of the polishing liquid collected by the pump action due to the rotational movement of the rotary vanes; this pressure creates the gap between the polishing table and the polishing pad, and new polishing liquid is periodically forced from the circumference into the gap, whereby the polishing liquid is uniformly distributed over the entire surface of the polished substrate. Further, the aspirating means for aspirating the polishing liquid is in communication with the vicinity of the central part of the polishing head to which the polishing pad is attached, whereby the new polishing liquid is periodically taken from the circumference into the gap between the polishing table and the polishing pad, created by the pressure of the polishing liquid collected by the pump action due to the rotational movement of the rotary vanes, and whereby the old polishing liquid used is aspirated from the vicinity of the central part of the polishing pad. Therefore, the polishing liquid is uniformly distributed over the entire surface of the polished substrate, which enables uniform polishing of the entire surface of the substrate.

The gap can also be created similarly between the polished substrate and the polishing pad by driving the vertical moving means of the polishing pad at the predetermined periods during the polishing process, whereby the new polishing liquid can be periodically taken from the circumference into the gap and whereby the polishing liquid can be aspirated from the vicinity of the central part of the polishing pad, which enables uniform polishing of the entire surface of the substrate.

Further, reuse of the polishing liquid can be achieved by filtering the polishing liquid aspirated from the vicinity of the central part of the polishing pad and adjusting the components thereof so as to permit circulation thereof.

### BRIEF DESCRIPTION OF THE DRAWINGS

FIG. 1 is a schematic structural diagram to show a partly sectional view of the structure of a precision polishing apparatus of the first embodiment;

FIG. 2 is a sectional view to schematically illustrate the structure of the major part of the precision polishing apparatus of the first embodiment;

FIG. 3 is a plan view of the polishing table in the precision polishing apparatus of the first embodiment;

FIG. 4A is a schematic sectional view to show a state in which the substrate is being polished in the precision polishing apparatus of the first embodiment, and FIG. 4B is a schematic sectional view to show a state in which a gap is created between the substrate and the polishing pad in the polishing process;

FIG. 5 is a plan view of the polishing table in a precision polishing apparatus of the second embodiment;

FIG. 6 is a diagram to explain a state of changing angles of a variable-angle rotary vane in the second embodiment;

FIG. 7 is a schematic side view to show an example of the chemical mechanical polishing apparatus which the inventor has carried out;

FIG. 8 is a schematic side view to show another example of the chemical mechanical polishing apparatus which the inventor has carried out; and

FIG. 9 is a schematic side view to show still another example of the chemical mechanical polishing apparatus which the inventor has carried out.

### DETAILED DESCRIPTION OF THE PREFERRED EMBODIMENTS

The embodiments of the present invention will be described based on the drawings.

(First Embodiment)

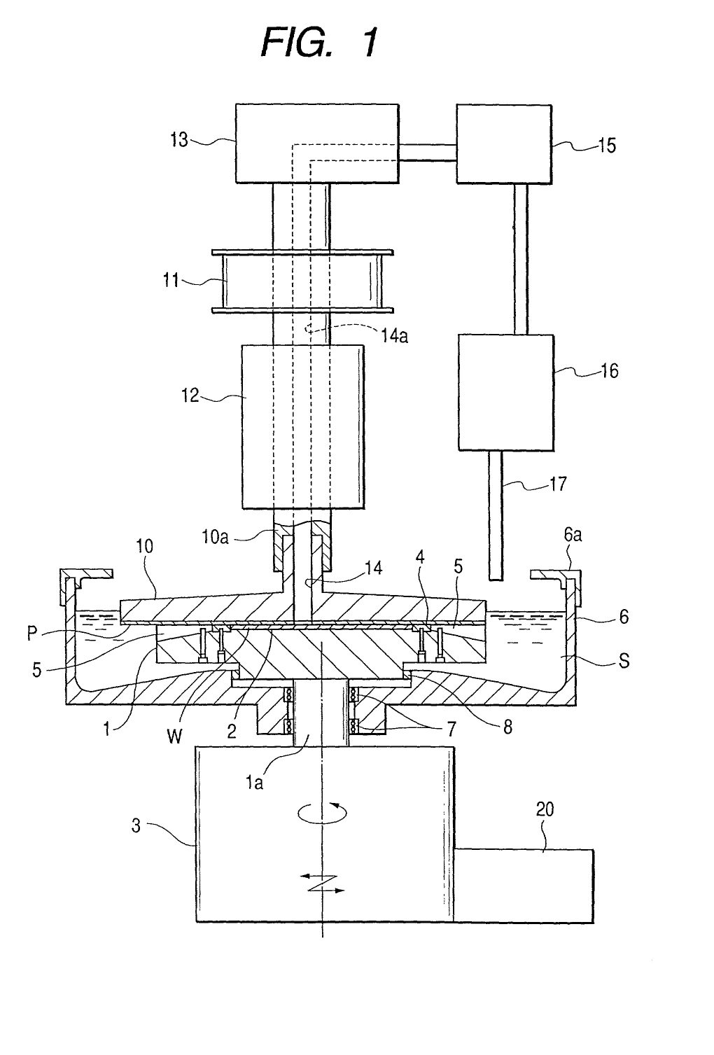

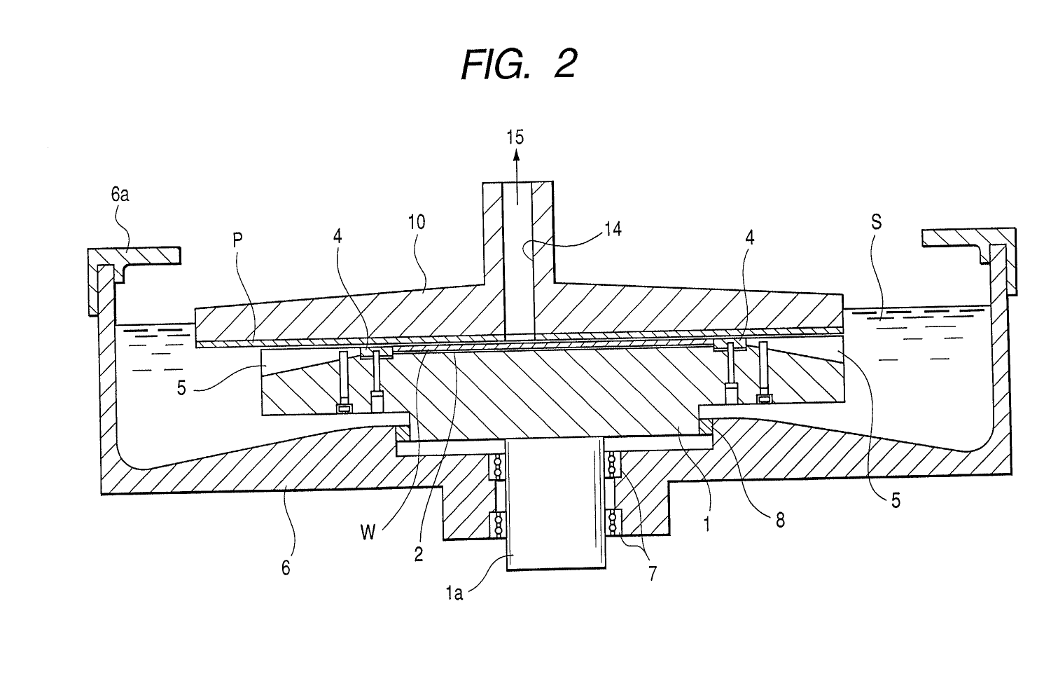

FIG. 1 is a schematic structural diagram to show a partly sectional view of the structure of the precision polishing apparatus of the present embodiment and FIG. 2 is a sectional view to schematically illustrate the major part of the precision polishing apparatus of the present embodiment.

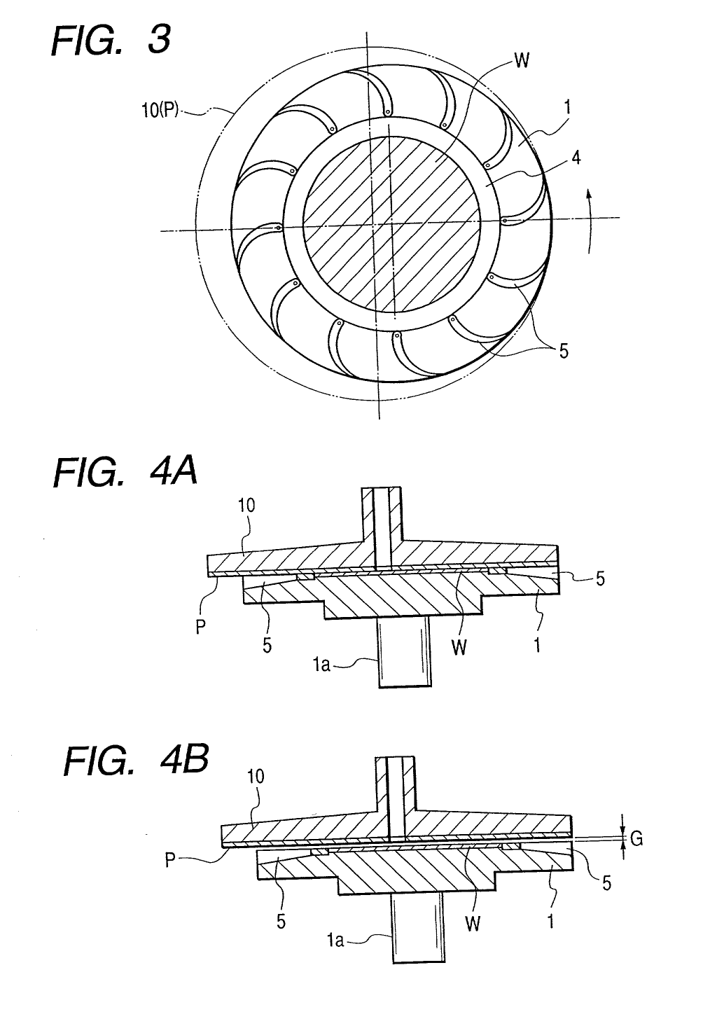

In FIG. 1 and FIG. 2, reference numeral 1 designates a polishing table provided with a substrate holding portion 2 for holding a substrate W such as a wafer, which is constructed so as to be rotationally driven through shaft la by first driving means 3. On the top surface of the polishing table 1, a guide ring 4 having the inside diameter corresponding to the size of the substrate W is fixed to the substrate holding portion 2 holding the substrate W by means of screws or the like and an annular slant surface inclined downward and radially outward is formed in the portion on the peripheral side of the guide ring 4. A plurality of rotary vanes 5 are arranged at equal intervals in the circumferential direction on the slant surface and are fixed to the polishing table 1 by screws or the like. These rotary vanes 5 are formed so that their top surfaces are at the same level as the top surface of the guide ring 4 and their lower surfaces are inclined gradually downward and radially outward as illustrated in FIG. 1 and FIG. 2 and so that they are curved against the rotating direction of the polishing table 1 as illustrated in FIG. 3. These rotary vanes 5 are integrally rotated with rotation of the polishing table 1 in a polishing liquid (slurry solution) S as detailed hereinafter to act as a pump for taking the slurry solution S present around them into the central part of the polishing table 1.

A slurry vessel 6 opening above, which is a container for accommodating the polishing liquid, is provided so as to surround the polishing table 1 and is mounted through bearings 7 on the shaft 1a of the polishing table 1 so as to permit rotation of the polishing table 1 in the vessel. Further, a seal member 8 is provided at a slide contact portion with the polishing table 1 so as to prevent the slurry solution S filling the slurry vessel 6 from leaking to the outside. Preferably, a scattering preventing cover 6a for preventing the scattering of the slurry solution is attached to the top opening part of the slurry vessel 6.

A polishing head 10 for detachably holding a polishing pad P has the diameter enough to hold the polishing pad P having the diameter ranging from the same as to not more than double the diameter of the substrate W, which is a body to be polished. The polishing head 10 is placed above the polishing table 1 and a shaft 10a of the polishing head 10 is coupled to a second driving means 11 for rotationally driving the polishing head 10, a vertical moving means 12 for vertically moving the polishing head 10 (and the polishing pad P) along the axial direction in the level of several cm to several mm, and an urging device 13 for urging the polishing pad P against the polished surface of the substrate W.

Through holes 14, 14a are bored in respective central parts of the polishing head 10 and its shaft 10a and these through holes 14, 14a in communication with each other are in communication with a slurry aspirating means 15 for aspirating the slurry solution S existing below the polishing pad P. The slurry aspirating means 15 is further in successive communication with a filter and component adjusting means 16 and with an outflow portion 17. Therefore, the apparatus is so constructed that the slurry aspirating means 15 can aspirate the slurry solution S supplied to between the substrate W and the polishing pad P, from the central part of the polishing pad P through the through hole 14 bored in the polishing head 10, that the slurry solution thus aspirated can be filtered and adjusted in components by the filter and component adjusting means 16, and that the slurry solution after adjustment of the components can be circulated from the outflow portion 17 to the slurry vessel 6. Numeral 20 denotes a rocking mechanism.

Next described is a polishing method of substrate by the precision polishing apparatus constructed as described above.

The substrate W to be polished is set on the substrate holding portion 2 of the polishing table 1 and is carried to immediately below the polishing head 10 equipped with the polishing pad P on the bottom surface. At this time, the polishing pad P has the diameter larger than that of the substrate W and the polishing head 10 equipped with the polishing pad P is greater than the diameter of the polishing table 1 holding the substrate W. The whole of the polishing table 1 is positioned so as to be located below the bottom surface within the area of the polishing pad P, the center axis of rotation of the polishing table 1 is positioned in a slightly deviated state from the center axis of rotation of the polishing head 10, and the polishing table 1 is positioned so that the plurality of rotary vanes 5 in the peripheral part thereof are located outside the effective polishing area of the polishing pad P.

The slurry vessel 6 surrounding the polishing table 1 and substrate W is filled with the slurry solution S and the polishing head 10 with the polishing pad P mounted on the bottom surface is moved by the vertical moving means 12 so as to make the polishing pad P go into contact with the polished surface of the substrate W and is urged under predetermined processing pressure by the urging means 13. The substrate W and polishing pad P both are dipped in the slurry solution S and, at the same time, the substrate W and polishing pad P are driven by the first driving means 3 of the polishing table 1 and by the second driving means 11 of the polishing head 10, respectively, to rotate, for example, at equal rotational speeds or at mutually different rotational speeds with a difference of several rpm or so, thus starting polishing. At this time, the polishing pad P or the substrate W is permitted to be rocked so as to enhance uniformity of polishing by averaging effect, within the scope not affecting the rotational speeds of the polishing pad and the substrate. In the present embodiment the substrate W is rocked by the rocking means 20 illustrated in FIG. 1.

Next described referring to FIG. 3 and FIGS. 4A and 4B is the supply of the slurry solution S to the contact surfaces of the substrate W and polishing pad P. The substrate W and polishing pad P both are rotationally driven with being dipped in the slurry solution S and the plurality of rotary vanes 5 fixed to the peripheral part of the polishing table 1 are also rotated (see FIG. 3 and FIG. 4A). The plurality of rotary vanes 5 act as a pump for forcing the slurry solution S around them into between the substrate W on the polishing table 1 and the polishing pad P by their rotational movement. Here, numeral 4 denotes the guide ring. Then polishing is carried out with changing the rotational speeds of the polishing table 1 and polishing head 10 at predetermined periods or at predetermined timing. The polishing table 1 is increased to a predetermined rotational speed by changing the rotational speeds of the polishing table 1 and polishing head 10 as described, whereupon the plurality of rotary vanes 5 acting as a pump start taking the slurry solution S around them into between the substrate W on the polishing table 1 and the polishing pad P, so as to increase the taking-in amount of the slurry solution S. This increases the pressure of the slurry solution S existing between the substrate W and the polishing pad P and this pressure of the slurry solution S creates a small gap G of approximately several cm or several mm between the substrate W and the polishing pad P (see FIG. 4B). Then new slurry solution S around the periphery flows into the gap G and the old slurry solution S, which has contributed heretofore to the polishing, is also aspirated through the through hole 14 in the central part of the polishing head 10 by the slurry aspirating means 15, whereby the new slurry solution S is uniformly distributed on the polished surface of the substrate W. Then the rotational speed of the polishing table 1 is returned to the previous rotational speed, whereupon the polishing pad P is again urged against the substrate W, thereby continuing the polishing. By changing the rotation of the polishing table 1 and polishing head 10 at the predetermined periods or at the predetermined timing as described above, the new slurry solution S is supplied to between the substrate W and the polishing pad P and the polishing can be carried out in a state in which the slurry solution S is always uniformly distributed on the polished surface of the substrate W, which enables uniform polishing of the entire surface of the substrate.

Likewise, the gap G can also be created similarly between the substrate W and the polishing pad P so as to allow the inflow and aspiration of the slurry solution S, by changing the urging force of the urging means 13 for urging the polishing head 10 at periodic or predetermined timing or by changing the urging force on the polishing head 10 in synchronism with the periodic change of the rotational speeds, instead of the periodic change of the rotational speeds of the polishing table 1 and polishing head 10. Describing in more detail, decrease of the urging force on the polishing pad P results in increasing the taking-in amount of the slurry solution S because of the pump action of the rotary vanes 5 to increase the pressure of the slurry solution S between the substrate W and the polishing pad P and create the small gap G between the substrate W and the polishing pad P. Then, just as described above, the old slurry solution S having contributed heretofore to the polishing is aspirated through the through hole 14 in the central part of the polishing head 10 by the slurry aspirating means 15 and the new slurry solution S around the vanes uniformly flow into the gap G so as to be uniformly distributed on the polished surface of the substrate W.

The flow rate of the slurry solution S aspirated through the through hole 14 in the central part of the polishing head 10 can be determined according to the rotational speed of the rotary vanes 5 and the urging force of the polishing pad P. The periods and timing of the change of the rotational speeds of the polishing table 1 and the polishing head 10 and the change of the urging pressure are set within the scope that assures continuation of uniform polishing rate and uniform thickness distribution.

The gap G can also be created between the polished surface of the substrate W and the polishing pad P by vertically moving the polishing head 10 or the polishing table 1 every fixed polishing time. For example, the vertical moving means 12 of the polishing head 10 with the polishing pad P is actuated at predetermined periods or at predetermined timing to create the gap G between the substrate W and the polishing pad P and the old slurry solution S is aspirated from the central part of the polishing pad P while the new slurry solution S around the periphery is forced into the gap G. This permits the slurry solution S to be uniformly distributed over the entire area of the polished surface of the substrate W, so that uniform polishing can be performed again in polishing the substrate after lowering and urging the polishing head 10. The periods of the vertical movement of the polishing head 10 can be set within the scope that assures continuation of uniform polishing rate and uniform thickness distribution. The gap G can also be created with certainty between the substrate W and the polishing pad P by effecting the vertical movement of the polishing head 10 in synchronism with the periodic change of the rotational speed of the polishing head 10.

The slurry solution S aspirated from near the central part of the polishing pad P flows through the slurry aspirating means 15 to the filter and component adjusting means 16, where it is filtered and adjusted in components as occasion may demand. The slurry solution S adjusted in components is allowed to flow from the outflow portion 17 back into the slurry vessel 6, which enables circulation and reuse of the slurry solution. Accordingly, the use amount of the slurry solution used for the polishing is some tenths of that in the conventional methods.

In the present embodiment the vertical driving means does not always have to be provided for the polishing head. For example, the polishing table may be arranged to move vertically or each of the polishing head and the polishing table may be provided with the vertical moving unit.

The substrates that can be polished by the precision polishing method and apparatus of the present embodiment include the SOI substrates, the semiconductor wafers such as Si, GaAs, or InP, the quartz or glass substrates on the surface of which a plurality of island-shape semiconductor regions are formed, and so on and either one of these substrates can be polished prior to, during, or after fabrication of functional devices such as resistors, diodes, or transistors. A substrate of a square shape for display can also be polished. Therefore, the polished surface of the substrate as a body to be polished is a semiconductor surface, an electrically insulating or conductive surface, or a surface of mixture thereof. The method and apparatus of the present embodiment can also polish a substrate having a metal such as aluminum, tungsten, or copper in the polished surface, as a substrate to be polished.

It is desirable to utilize a surface of a pad such as nonwoven fabric or foamed polyurethane, as the polishing pad used for the polishing. It is also preferable to use a member of Teflon or the like with excellent chemical resistance as the polishing pad.

The slurry solution (polishing liquid) used in the present embodiment is a liquid containing fine particles. Specifically, the fine particles are those of one selected from silicon oxide (SiO₂ etc.), aluminum oxide (Al₂O₃ etc.), manganese oxide (MnO₂, Mn₂O₃, Mn₃O₄, etc.), cerium oxide (CeO, CeO₂, etc.), yttrium oxide (Y₂O₃ etc.), molybdenum oxide (MoO₂ etc.), calcium oxide (CaO₂ etc.), magnesium oxide (MgO etc.), tin oxide (SnO₂ etc.), and so on, and the liquid is one containing either one selected from sodium hydroxide (NaOH), potassium hydroxide (KOH), hydrogen peroxide (H₂O₂), and so on. Alternatively, the polishing can also be carried out by combination of etching action with mechanical polishing, using as a polishing liquid only a chemical solution not containing the polishing grains such as the above fine particles. This chemical solution is an acid solution containing hydrogen chloride, iron chloride, or the like, or an alkali solution. Since the rotary vanes can take in the fresh polishing liquid with high etching action in the present embodiment, the polishing can be performed with high performance.

Grain sizes of the fine particles are preferably 8 nm to 50 nm, and the degree of aggregation of particles can be controlled, for example, by changing pH of KOH. The polishing amount can be changed according to the degree of aggregation.

Either one of these slurry solutions is properly selected according to the polished surface; a silica-dispersed sodium hydroxide solution is used for polishing of semiconductor surfaces; a silica-dispersed potassium hydroxide solution is preferably used for polishing of insulating films; aluminum-oxide-dispersed or manganese-oxide-dispersed hydrogen peroxide is preferably used for polishing of metal films such as tungsten.

The vertical moving means of the polishing pad can be actuated in synchronism with the predetermined periods of change of set angles of the rotary vanes during polishing to create the gap between the polished substrate and the polishing pad with reliability, whereby the new polishing liquid can be taken from the surroundings into the gap while the old polishing liquid can aspirated from near the central part of the polishing pad by the aspirating means, which enables uniform polishing of the entire surface of the substrate.

Further, reuse of the polishing liquid can be enabled by filtering the polishing solution aspirated from near the central part of the polishing pad and adjusting the components thereof so as to permit circulation thereof.

The present embodiment may also be modified so that the rotatable polishing head is provided with the rotary vanes, if the rotary vanes are arranged to take the polishing liquid into between the polishing pad and the polished substrate by pressure exerted thereon by the polishing liquid.

And the present embodiment may also be modified so that either one member without the rotary vanes out of the polishing head and the polishing table may be arranged not to rotate.

And the present embodiment may also be modified so that the polishing head may also be placed under the holding member of the polished substrate.

A further embodiment of the present invention will be described based on the drawings.

(Second Embodiment)

FIG. 1 is the schematic structural diagram to show the partly sectional view of the structure of the precision polishing apparatus of the present embodiment and FIG. 2 is the sectional view to schematically illustrate the major part of the precision polishing apparatus of the present embodiment. The present embodiment is characterized by-provision of the rotary vanes in variable-angle structure in the peripheral part. The present embodiment is substantially the same as the first embodiment except for this feature.

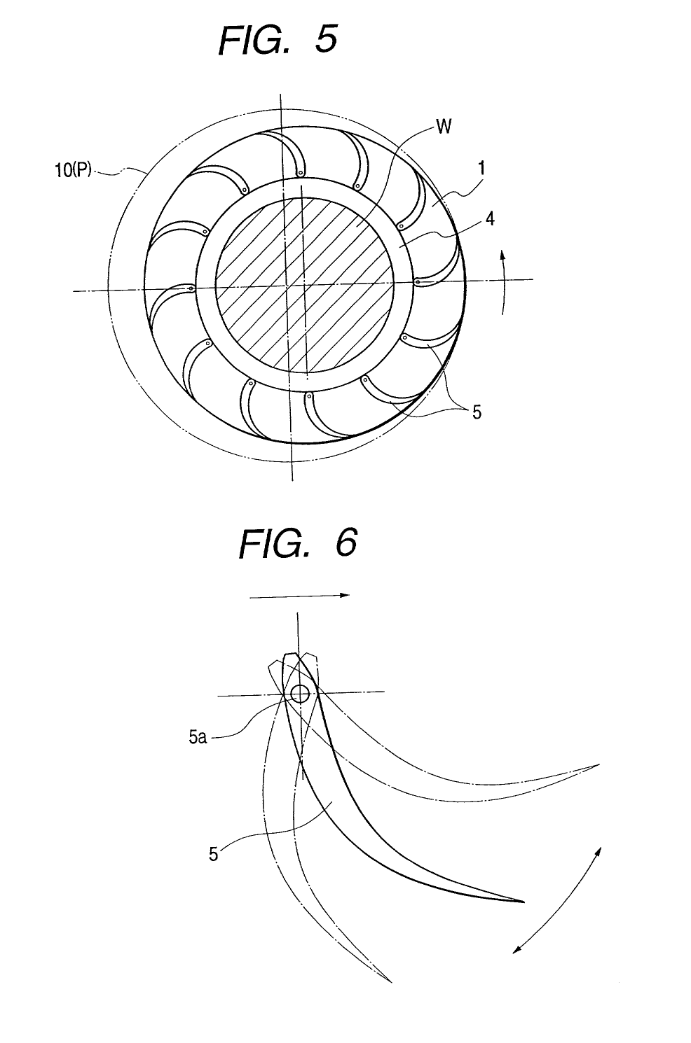

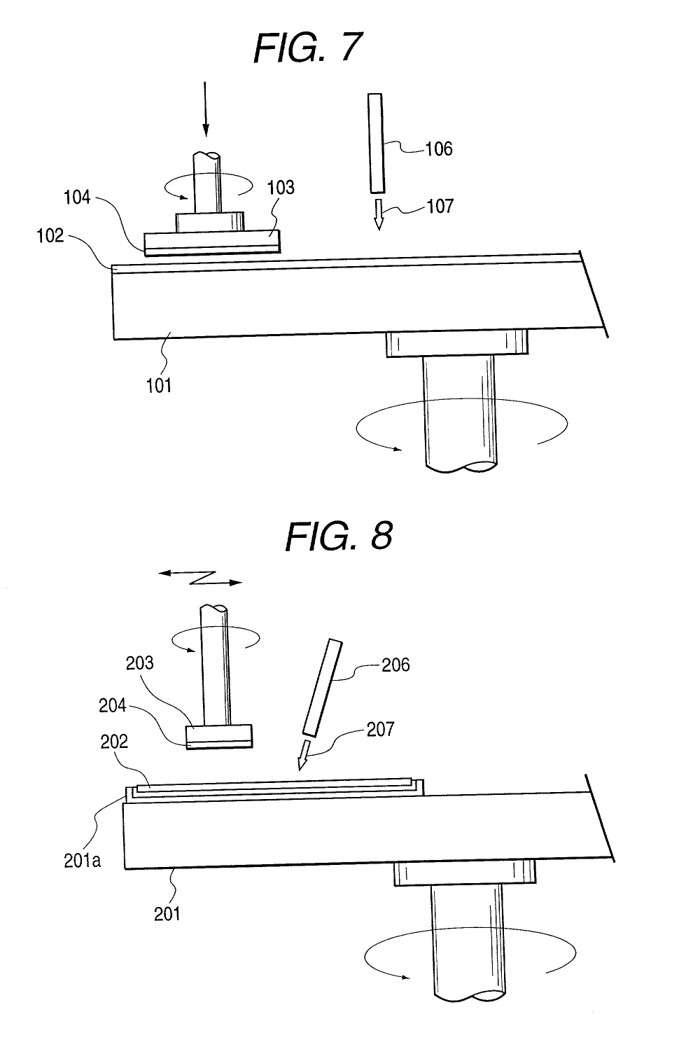

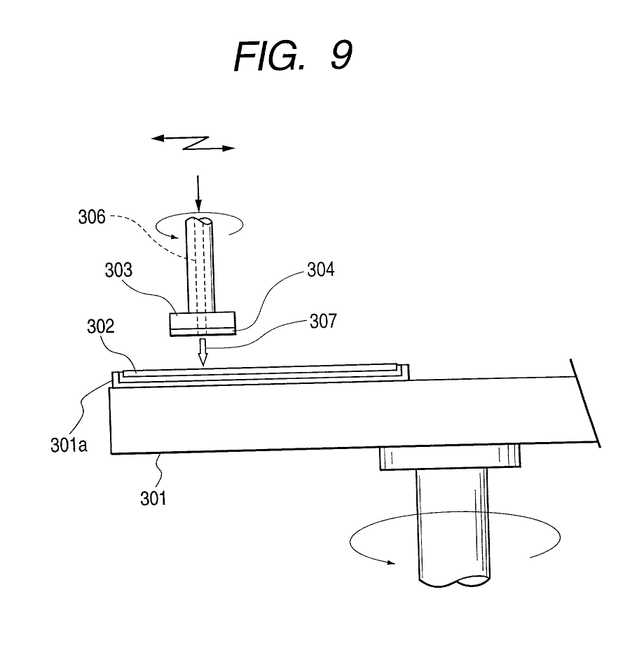

As illustrated in FIG. 5 and FIG. 6, the rotary vanes 5 are curved against the rotating direction of the polishing table 1 and are supported on respective shafts 5a on the internal base side so as to permit adjustment of angles in the present embodiment. The adjustment of angles of these rotary vanes 5 is carried out manually or automatically with an angle adjusting device not illustrated. Therefore, the angles of the rotary vanes 5 can be preliminarily adjusted manually before a start of polishing or they can also be automatically adjusted during polishing by use of the angle adjusting device not illustrated. These rotary vanes 5 are rotated simultaneously with rotation of the polishing table 1 in the polishing liquid (slurry solution) S as described hereinafter and act as a pump for taking the slurry solution S around them into the central part of the polishing table 1. Further, collection efficiency (pressure) of the slurry solution S can be adjusted (increased or decreased) by changing the set angles of the rotary vanes (see FIG. 6).

Next described is a polishing method of substrate by the precision polishing apparatus constructed as described above. The polishing method in the present embodiment is characterized in that the taking-in amount of the polishing solution is adjusted by arbitrarily setting the angles of the variable-angle rotary vanes. The present embodiment is substantially the same as the first embodiment except for this feature.

The collection efficiency (pressure) of the slurry solution S is increased by changing the set angles of the variable-angle rotary vanes 5. The set angles of the variable-angle rotary vanes 5 are changed every predetermined polishing time during the polishing, whereby the collection efficiency (pressure) of the rotary vanes 5 is increased or decreased, or, whereby the amount of the slurry solution S taken into between the substrate W on the polishing table 1 and the polishing pad P is increased or decreased.

By changing the urging force of the polishing head 10 in synchronism with the periodic change of the set angles of the variable-angle rotary vanes 5 as described above, the gap G can be created with certainty between the substrate W and the polishing pad P and the inflow and aspiration of the slurry solution S can be performed with reliability.

The periods or timing of the change of the set angles of the variable-angle rotary vanes is set within the scope that permits continuation of uniform polishing rate and uniform thickness distribution. The flow rate of the slurry solution S aspirated through the through hole 14 in the central part of the polishing head 10 can be determined according to the urging force of the polishing pad P, and the rotational speed and set angles of the rotary vanes 5.

Further, the apparatus may also be so arranged that the set angles of the variable-angle rotary vanes 5 are changed at predetermined periods or timing and that, in synchronism therewith, the polishing head 10 or the polishing table 1 is moved vertically, whereby the gap G can be created with certainty between the substrate W and the polishing pad P, whereby the old slurry solution S can be aspirated from the central part of the polishing pad P, and whereby the new slurry solution S around the vanes can be forced into the gap G. This permits the slurry solution S to be uniformly distributed over the entire area of the polished surface of the substrate W, so that uniform polishing can be performed in the next operation of again lowering the polishing head 10, urging the polishing pad P against the substrate W, and polishing it.

Since the present invention involves the structures as described above, the old polishing liquid can be periodically aspirated from the central part of the polishing pad and the new polishing liquid can be always uniformly distributed on the polished surface. Therefore, efficient and uniform polishing can be performed and the polishing liquid can be used in circulation readily. The use amount of the polishing liquid used for polishing can thus be decreased drastically as compared with the conventional methods. This greatly decreases the running cost. Since the size of the polishing pad is small, exchange of the polishing pad is also easy.

What is claimed is:

1. A precision polishing method of substrate for urging a polishing pad attached to a polishing head under a predetermined processing pressure against a polished surface of a polished substrate and supplying a polishing liquid to between said polishing pad and said polished surface of said polished substrate to polish the polished surface,
wherein at least said polished surface of said polished substrate and a polishing surface of said polishing pad are dipped in the polishing liquid and wherein said polishing liquid is periodically taken from a circumference into between said polished surface of said polished substrate and said polishing surface of said polishing pad by a plurality of rotary vanes fixed to a peripheral part of a polishing table holding said polished substrate.

2. The precision polishing method of substrate according to claim 1, wherein polishing is carried out with changing rotational speeds of said polishing table holding said polished substrate and said polishing head to which said polishing pad is attached, at predetermined periods or at predetermined timing.

3. The precision polishing method of substrate according to claim 1, wherein polishing is carried out with changing said processing pressure working between said polishing head to which said polishing pad is attached and said polishing table holding said polished substrate, at predetermined periods or at predetermined timing.

4. The precision polishing method of substrate according to claim 1, wherein polishing is carried out with vertically moving said polishing head to which said polishing pad is attached, at predetermined periods or at predetermined timing during a polishing process.

5. The precision polishing method of substrate according to claim 1, wherein an aspirating means for aspirating said polishing liquid is provided in communication with a vicinity of a central part of said polishing pad and is arranged to aspirate said polishing liquid taken into between said polishing surface of said polishing pad and said polished surface of said polished substrate, from the vicinity of the central part of said polishing pad.

6. The precision polishing method of substrate according to claim 5, wherein said polishing liquid is circulated with filtering said polishing liquid aspirated from the vicinity of the central part of said polishing head to which said polishing pad is attached, and then adjusting components thereof.

7. A precision polishing apparatus of substrate for urging a polishing pad attached to a polishing head under a predetermined processing pressure against a polished surface of a polished substrate and supplying a polishing liquid to between said polishing pad and said polished surface of said polished substrate to polish the polished surface,
said apparatus comprising a polishing table comprising a substrate holding portion for holding said polished substrate and arranged to be rotationally driven by a first driving means, wherein a plurality of rotary vanes are fixed to a peripheral part of said substrate holding portion of said polishing table, wherein at least said polished surface of said polished substrate and a polishing surface of said polishing pad are dipped in the polishing liquid, and wherein said polishing liquid is periodically taken from a circumference into between said polished surface of said polished substrate and said polishing surface of said polishing pad by rotational movement of said rotary vanes.

8. A precision polishing apparatus of substrate comprising a polishing table comprising a substrate holding portion for holding a polished substrate and arranged to be rotationally driven by a first driving means, a polishing head to which a polishing pad is detachably attached so that a polishing surface thereof faces said polished substrate and which is arranged to be rotationally driven by a second driving means, a vertical moving means for vertically moving said polishing head in the axial direction, and an urging means for urging said polishing surface of said polishing pad against said polished substrate, said apparatus being adapted for urging said polishing pad attached to said polishing head under a predetermined processing pressure against said polished surface of said polished substrate and supplying a polishing liquid to between said polishing pad and said polished substrate to polish the polished surface,
wherein a plurality of rotary vanes are fixed to a peripheral part of said substrate holding portion of said polishing table, wherein at least said polished surface of said polished substrate and said polishing surface of said polishing pad are dipped in the polishing liquid, and wherein said polishing liquid is periodically taken from a circumference into between said polished surface of said polished substrate and said polishing surface of said polishing pad by rotational movement of said rotary vanes.

9. The precision polishing apparatus of substrate according to claim 7 or 8, wherein said plurality of rotary vanes are positioned and fixed outside an effective polishing area of said polishing pad.

10. The precision polishing apparatus of substrate according to claim 7 or 8, wherein polishing is carried out with changing rotational speeds of said polishing table holding said polished substrate and said polishing head at predetermined periods or at predetermined timing.

11. The precision polishing apparatus of substrate according to claim 7 or 8, wherein polishing is carried out with changing said processing pressure at predetermined periods or at predetermined timing.

12. The precision polishing apparatus of substrate according to claim 7 or 8, wherein polishing is carried out with vertically moving said polishing head to which said polishing pad is attached, at predetermined periods or at predetermined timing during a polishing process.

13. The precision polishing apparatus of substrate according to claim 7 or 8, comprising an aspirating means in communication with a vicinity of a central part of said polishing head, said aspirating means being adapted for aspirating said polishing liquid taken into between said polishing surface of said polishing pad and said polished surface of said polished substrate, from the vicinity of the central part of said polishing pad.

14. The precision polishing apparatus of substrate according to claim 13, comprising a means for filtering the polishing liquid aspirated from the vicinity of the central part of said polishing head to which said polishing pad is attached and for adjusting components thereof, and a means for circulating said polishing liquid thus aspirated.

15. A precision polishing method of substrate for urging a polishing pad attached to a polishing head under a predetermined processing pressure against a polished surface of a polished substrate and supplying a polishing liquid to between said polishing pad and said polished surface of said polished substrate to polish the polished surface,
wherein at least said polished surface of said polished substrate and a polishing surface of said polishing pad are dipped in the polishing liquid and wherein said polishing liquid is periodically taken from a circumference into between said polished surface of said polished substrate and said polishing surface of said polishing pad by a plurality of variable-angle rotary vanes provided on a peripheral part of a polishing table holding said polished substrate.

16. The precision polishing method of substrate according to claim 15, wherein polishing is carried out with changing set angles of said plurality of variable-angle rotary vanes at predetermined periods or at predetermined timing.

17. The precision polishing method of substrate according to claim 16, wherein polishing is carried out with changing said processing pressure working between said polishing head to which said polishing pad is attached and said polishing table holding said polished substrate, in synchronism with the predetermined periods or with the predetermined timing for changing said set angles of said rotary vanes.

18. The precision polishing method of substrate according to claim 16, wherein polishing is carried out with vertically moving said polishing head to which said polishing pad is attached, in synchronism with said predetermined periods or with said predetermined timing for changing said set angles of said rotary vanes.

19. The precision polishing method of substrate according to claim 15, wherein an aspirating means for aspirating said polishing liquid is provided in communication with a vicinity of a central part of said polishing pad and is arranged to aspirate said polishing liquid taken into between said polishing surface of said polishing pad and said polished surface of said polished substrate, from the vicinity of the central part of said polishing pad.

20. The precision polishing method of substrate according to claim 19, wherein said polishing liquid is circulated with filtering said polishing liquid aspirated from the vicinity of the central part of said polishing head to which said polishing pad is attached, and then adjusting components thereof.

21. A precision polishing apparatus of substrate for urging a polishing pad attached to a polishing head under a predetermined processing pressure against a polished surface of a polished substrate and supplying a polishing liquid to between said polishing pad and said polished surface of said polished substrate to polish the polished surface,
said apparatus comprising a polishing table comprising a substrate holding portion for holding said polished substrate and arranged to be rotationally driven by a first driving means, wherein a plurality of variable-angle rotary vanes are provided on a peripheral part of said substrate holding portion of said polishing table, wherein at least said polished surface of said polished substrate and a polishing surface of said polishing pad are dipped in the polishing liquid, and wherein said polishing liquid is periodically taken from a circumference into between said polished surface of said polished substrate and said polishing surface of said polishing pad by rotational movement of said variable-angle rotary vanes.

22. A precision polishing apparatus of substrate comprising a polishing table comprising a substrate holding portion for holding a polished substrate and arranged to be rotationally driven by a first driving means, a polishing head to which a polishing pad is detachably attached so that a polishing surface thereof faces said polished substrate and which is arranged to be rotationally driven by a second driving means, a vertical moving means for vertically moving said polishing head in the axial direction, and an urging means for urging said polishing surface of said polishing pad against said polished substrate, said apparatus being adapted for urging said polishing pad attached to said polishing head under a predetermined processing pressure against said polished surface of said polished substrate and supplying a polishing liquid to between said polishing pad and said polished substrate to polish the polished surface,
wherein a plurality of variable-angle rotary vanes are provided on a peripheral part of said substrate holding portion of said polishing table, wherein at least either one of said polished surface of said polished substrate and said polishing surface of said polishing pad is dipped in the polishing liquid, and wherein said polishing liquid is periodically taken from a circumference into between said polished surface of said polished substrate and said polishing surface of said polishing pad by rotational movement of said variable-angle rotary vanes.

23. The precision polishing apparatus of substrate according to claim 21 or 22, wherein said plurality of variable-angle rotary vanes are positioned and fixed outside an effective polishing area of said polishing pad.

24. The precision polishing apparatus of substrate according to claim 21 or 22, wherein polishing is carried out with changing set angles of said plurality of variable-angle rotary vanes at predetermined periods or at predetermined timing.

25. The precision polishing apparatus of substrate according to claim 24, wherein polishing is carried out with changing said processing pressure in synchronism with the predetermined periods or with the predetermined timing for changing said set angles of said rotary vanes.

26. The precision polishing apparatus of substrate according to claim 24, wherein polishing is carried out with vertically moving said polishing head to which said polishing pad is attached, in synchronism with said predetermined periods or with said predetermined timing for changing said set angles of said rotary vanes.

27. The precision polishing apparatus of substrate according to claim 21 or 22, comprising an aspirating means in communication with a vicinity of a central part of said polishing head, said aspirating means being adapted for aspirating said polishing liquid taken into between said polishing surface of said polishing pad and said polished surface of said polished substrate, from the vicinity of the central part of said polishing pad.

28. The precision polishing apparatus of substrate according to claim 27, comprising a means for filtering the polishing liquid aspirated from the vicinity of the central part of said polishing head to which said polishing pad is attached and for adjusting components thereof, and a means for circulating said polishing liquid thus aspirated.

29. A precision polishing method of substrate for polishing a polished surface while supplying a polishing liquid to between a polishing pad and said polished surface,
said method comprising:
a step of rotating in said polishing liquid a polishing table provided with a plurality of rotary vanes on a peripheral part of a substrate holding portion for holding said polished substrate; and
a step of vertically moving at least either one of a polishing head detachably holding said polishing pad and said polishing table,
wherein said polished surface is polished with taking said polishing liquid from a circumference into between said polished substrate and said polishing pad.

30. The precision polishing method according to claim 29, wherein said rotary vanes are fixed to said peripheral part.

31. The precision polishing method according to claim 29, wherein said rotary vanes are mounted in variable-angle structure on said peripheral part.

32. The precision polishing method according to any one of claims 1 to 8; 15 to 22; and 29, wherein said polishing liquid is a chemical solution containing no polishing grain.

33. The precision polishing method according to claim 9, wherein said polishing liquid is a chemical solution containing no polishing grain.

34. The precision polishing method according to claim 10, wherein said polishing liquid is a chemical solution containing no polishing grain.

35. The precision polishing method according to claim 11, wherein said polishing liquid is a chemical solution containing no polishing grain.

36. The precision polishing method according to claim 12, wherein said polishing liquid is a chemical solution containing no polishing grain.

37. The precision polishing method according to claim 13, wherein said polishing liquid is a chemical solution containing no polishing grain.

38. The precision polishing method according to claim 14, wherein said polishing liquid is a chemical solution containing no polishing grain.

39. The precision polishing method according to claim 23, wherein said polishing liquid is a chemical solution containing no polishing grain.

40. The precision polishing method according to claim 24, wherein said polishing liquid is a chemical solution containing no polishing grain.

41. The precision polishing method according to claim 25, wherein said polishing liquid is a chemical solution containing no polishing grain.

42. The precision polishing method according to claim 26, wherein said polishing liquid is a chemical solution containing no polishing grain.

43. The precision polishing method according to claim 27, wherein said polishing liquid is a chemical solution containing no polishing grain.

44. The precision polishing method according to claim 28, wherein said polishing liquid is a chemical solution containing no polishing grain.

45. A precision polishing apparatus of substrate comprising a polishing table detachably holding a polished substrate, and a polishing head detachably holding a polishing pad, said apparatus being adapted for polishing said polished substrate while supplying a polishing liquid to between said polishing pad and said polished substrate,
said apparatus comprising:
a rotating means for rotating said polishing table;
a plurality of rotary vanes provided on a peripheral part of a substrate holding portion of said polishing table;
a vessel retaining said polishing liquid and permitting said plurality of rotary vanes to be dipped in said polishing liquid; and
a vertical driving means for vertically moving at least either one of said polishing head and said polishing table.

46. The precision polishing apparatus according to claim 45, wherein rotation of said polishing table causes said plurality of rotary vanes to take said polishing liquid from a circumference into between said polished substrate and said polishing head.

47. The precision polishing apparatus according to claim 45, wherein said rotary vanes are fixed to said peripheral part.

48. The precision polishing apparatus according to claim 45, wherein said rotary vanes are mounted in variable-angle structure on said peripheral part.

49. A precision polishing method of substrate for polishing a polished substrate while supplying a polishing liquid to between a polishing pad and said polished substrate,
said method comprising:
a step of rotating a holding means detachably holding either one of said polishing pad and said polished substrate; and
a step of taking said polishing liquid retained in a vessel into between said polishing pad and said polished substrate by a plurality of rotary vanes provided on a peripheral part of said holding means with rotation of said holding means;
whereby said polished surface is polished.

50. A precision polishing apparatus of substrate comprising a polishing head and a holding means for holding a polished substrate, said apparatus being adapted for polishing said polished substrate while supplying a polishing liquid to between said polishing head and said holding means,
said apparatus comprising:
a vessel for retaining the polishing liquid;
a plurality of rotary vanes provided on at least either one of said polishing head and said holding means; and
a rotation driving means for rotating at least either one of said polishing head and said holding means having said rotary vanes,
wherein at least either one of said polishing head and said holding means is placed so that said rotary vanes can be dipped in said polishing liquid retained in said vessel.
